(19) United States
(12) Patent Application Publication
(10) Pub. No.: US 2010/0078735 A1
(43) Pub. Date: Apr. 1, 2010

(54) CMOS DEVICE COMPRISING NMOS TRANSISTORS AND PMOS TRANSISTORS HAVING INCREASED STRAIN-INDUCING SOURCES AND CLOSELY SPACED METAL SILICIDE REGIONS

(76) Inventors: Jan Hoentschel, Dresden (DE); Robert Mulfinger, Dresden (DE); Uwe Griebenow, Markkleeberg (DE)

Correspondence Address: WILLIAMS, MORGAN & AMERSON, 10333 RICHMOND, SUITE 1100, HOUSTON, TX, 77042, US

(21) Appl. No.: 12/493,788

(22) Filed: Jun. 29, 2009

(30) Foreign Application Priority Data
Sep. 30, 2008 (DE) 10 2008 049 725.8

(51) Int. Cl. H01L 29/78; H01L 21/336

(52) U.S. Cl. 257/408; 438/299; 257/E21.409; 257/E29.255

(57) ABSTRACT

In a CMOS manufacturing process flow, a cap layer formed on top of a gate electrode material may be maintained throughout the entire implantation sequence for defining the drain and source regions and may be removed during an etch process in which the width of a sidewall spacer structure may be reduced so as to reduce a lateral offset of metal silicide regions and of a stressed dielectric material. Thus, overall enhanced transistor performance may be obtained while nevertheless providing a high degree of compatibility with existing CMOS process strategies.

### BACKGROUND OF THE INVENTION

1. Field of the Invention

Generally, the subject matter disclosed herein relates to integrated circuits, and, more particularly, to transistors having strained channel regions by using stress sources, such as stressed overlayers, a strained semiconductor alloy in drain and source areas and the like, to enhance charge carrier mobility in the channel region of a MOS transistor.

2. Description of the Related Art

Generally, a plurality of process technologies are currently practiced in the field of semiconductor production, wherein, for complex circuitry, such as microprocessors, storage chips and the like, CMOS technology is currently the most promising approach due to the superior characteristics in view of operating speed and/or power consumption and/or cost efficiency. During the fabrication of complex integrated circuits using CMOS technology, millions of transistors, i.e., N-channel transistors and P-channel transistors, are formed on a substrate including a crystalline semiconductor layer. A MOS transistor, irrespective of whether an N-channel transistor or a P-channel transistor is considered, comprises so-called PN junctions that are formed by an interface of highly doped drain and source regions with an inversely or weakly doped channel region disposed between the drain region and the source region. The conductivity of the channel region, i.e., the drive current capability of the conductive channel, is controlled by a gate electrode formed near the channel region and separated therefrom by a thin insulating layer. The conductivity of the channel region, upon formation of a conductive channel due to the application of an appropriate control voltage to the gate electrode, depends on the dopant concentration, the mobility of the charge carriers and, for a given extension of the channel region in the transistor width direction, on the distance between the source and drain regions, which is also referred to as channel length. Hence, in combination with the capability of rapidly creating a conductive channel below the insulating layer upon application of the control voltage to the gate electrode, the overall conductivity of the channel region, in combination with the drain and source regions, substantially determines the performance of the MOS transistors. Thus, the reduction of the channel length is a dominant design criterion for accomplishing an increase in the operating speed and packing density of the integrated circuits.

The continuing shrinkage of the transistor dimensions, however, involves a plurality of issues associated therewith that have to be addressed so as to not unduly offset the advantages obtained by steadily decreasing the channel length of MOS transistors. One major problem in this respect is to provide low sheet and contact resistivity in drain and source regions and any contacts connected thereto and to maintain channel controllability. For example, reducing the channel length may necessitate an increase of the capacitive coupling between the gate electrode and the channel region, which may call for reduced thickness of the gate insulation layer. Presently, the thickness of silicon dioxide based gate insulation layers is in the range of 1-2 nm, wherein a further reduction may be less desirable in view of leakage currents, which typically exponentially increase when reducing the gate dielectric thickness.

The continuous size reduction of the critical dimensions, i.e., the gate length of the transistors, thus necessitates the adaptation and possibly the new development of highly complex process techniques concerning the above-identified problems. It has, therefore, been proposed to improve transistor performance by enhancing the channel conductivity of the transistor elements by increasing the charge carrier mobility in the channel region for a given channel length, thereby offering the potential of achieving a performance improvement that is comparable with the advance to a future technology node while avoiding or at least postponing many of the above-mentioned problems, such as gate dielectric scaling. One efficient mechanism for increasing the charge carrier mobility is the modification of the lattice structure in the channel region, for instance, by creating tensile or compressive stress in the vicinity of the channel region so as to produce a corresponding strain in the channel region, which results in a modified mobility for electrons and holes, respectively. For example, for standard silicon substrates, creating tensile strain in the channel region increases the mobility of electrons, which in turn may directly translate into a corresponding increase in the conductivity and thus drive current and operating speed. On the other hand, compressive strain in the channel region may increase the mobility of holes, thereby providing the potential for enhancing the performance of P-type transistors. The introduction of stress or strain engineering into integrated circuit fabrication is an extremely promising approach for further device generations, since, for example, strained silicon may be considered as a “new” type of semiconductor material, which may enable the fabrication of fast powerful semiconductor devices without requiring expensive semiconductor materials, while many of the well-established manufacturing techniques may still be used.

According to one promising approach for creating strain in the channel region of transistor elements, the dielectric material that is formed above the basic transistor structure may be provided in a highly stressed state so as to induce a desired type of strain at the transistor and in particular in the channel region thereof. For example, the transistor structures are typically enclosed by an interlayer dielectric material, which may provide the desired mechanical and electrical integrity of the individual transistor structures and which may provide a platform for the formation of additional wiring layers, which are typically required for providing the electrical interconnections between the individual circuit elements. That is, a plurality of wiring levels or metallization layers may typically be provided which may include horizontal metal lines and vertical vias including appropriate conductive materials for establishing the electrical connections. Consequently, an appropriate contact structure has to be provided which connects the actual circuit elements, such as transistors, capacitors and the like, or respective portions thereof, with the very first metallization layer. For this purpose, the interlayer dielectric material has to be appropriately patterned in order to provide respective openings connecting to the desired contact areas of the circuit elements, which may typically be accomplished by using an etch stop material in combination with the actual interlayer dielectric material.

For example, silicon dioxide is a well-established interlayer dielectric material, in combination with silicon nitride, which may act as an efficient etch stop material during the formation of the contact openings. Consequently, the etch stop material, i.e., the silicon nitride material, is positioned in close proximity to the basic transistor structure and thus may be efficiently used for inducing strain in the transistors, in particular as silicon nitride may be deposited on the basis of well-established plasma enhanced chemical vapor deposition (CVD) techniques with high internal stress. For instance, silicon nitride may be deposited with high internal compressive stress of up to 2 GPa and even higher by selecting appropriate deposition parameters. On the other hand, a moderately high internal tensile stress level may be created to 1 GPa and higher by appropriately adjusting the process parameters, for instance in particular the degree of ion bombardment during the deposition of the silicon nitride material. Consequently, the magnitude of the strain created in the channel region of a transistor element may depend on the internal stress level of the dielectric etch stop material and the thickness of stressed dielectric material in combination with the effective offset of the highly stressed dielectric material with respect to the channel region.

Consequently, in view of enhancing transistor performance, it may be desirable to increase the internal stress level and also provide enhanced amounts of highly stressed dielectric material in the vicinity of the transistor element, while also positioning the stressed dielectric material as closely as possible to the channel region. It turns out, however, that the internal stress levels of silicon nitride material may be restricted by the overall deposition capabilities of presently available plasma enhanced CVD techniques, while also the effective layer thickness may be substantially determined by the basic transistor topography and the distance between neighboring circuit elements. Consequently, although providing significant advantages, the efficiency of the stress transfer mechanism may significantly depend on process and device specifics and may result in reduced performance gain for well-established standard transistor designs having gate lengths of 50 nm and less, since the given device topography and the gap fill capabilities of the respective deposition process for the small spacing between neighboring gate electrode structures in densely packed device regions, in combination with a moderately high offset of the highly stressed material from the channel region caused by sophisticated spacer structures, may reduce the finally obtained strain in the channel region.

In other approaches, performance of transistors, such as P-channel transistors, may be enhanced by providing a strain-inducing semiconductor alloy at least in portions of the drain and source areas, which may create a desired type of strain in the adjacent channel region. For this purpose, frequently, a silicon/germanium mixture or alloy may be used which may be epitaxially grown on a silicon template material, thereby creating a strained state of the silicon/germanium alloy, which may exert a certain stress on the adjacent channel region, thereby creating the desired type of strain therein. The magnitude of the strain in the channel region may be adjusted on the basis of the size of the respective cavities in which the silicon/germanium alloy may be grown and by the amount of the germanium concentration in the semiconductor alloy. Typically, the lateral offset with respect to the channel region may be adjusted on the basis of a respective spacer structure formed on sidewalls of the gate electrode, which may act as an etch mask and a growth mask during etching the cavities and epitaxially depositing the silicon/germanium material. The corresponding spacer structure may be removed, along with a corresponding mask layer that may cover other transistors, and thereafter the further processing may be continued by forming the drain and source regions by ion implantation and anneal techniques. In many approaches, the above-described strain-inducing mechanisms may be combined, i.e., a strain-inducing semiconductor alloy may be provided together with a stressed dielectric material in the contact level, thereby requiring sophisticated masking regimes and spacer structures for defining the corresponding lateral offsets of the strain-inducing semiconductor alloy, the deep drain and source regions, any metal silicide regions formed therein and the like, which may have in combination a significant effect on the overall transistor performance. Moreover, when sophisticated device geometries are considered, in which a distance between neighboring gate electrode structures may be 100 nm or even less, the efficiency of some of these strain-inducing mechanisms may be reduced due to device specific constraints, for instance with respect to fill capability of deposition techniques, the requirement for a specified offset of the drain and source regions and the like. Consequently, in sophisticated applications, the performance gain obtained by strain-inducing mechanisms may be less pronounced, as expected.

The present disclosure is directed to various methods and devices that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure relates to semiconductor devices and methods for forming the same in which transistor performance may be enhanced by providing a less pronounced surface topography, at least prior to the deposition of a strain-inducing dielectric material above the basic transistor configuration, by reducing the width of a corresponding sidewall spacer structure, while also providing the possibility of maintaining a cap layer on gate electrode structures that may be used as an efficient implantation mask for reducing penetration of ions into sensitive device areas, such as gate dielectrics, channel regions and the like, while also providing enhanced protection during the process of reducing the size of the sidewall spacer structure. In some illustrative aspects disclosed herein, the cap layer removal and the reduction in size of the sidewall spacer structure may be accomplished in a single wet chemical etch step, thereby providing a highly efficient manufacturing sequence with a high degree of controllability with respect to adjusting the final spacer width. Moreover, in some aspects, the metal silicide regions may be formed on the basis of the reduced spacer width, thereby reducing an offset of the metal silicide regions with respect to the channel region, which may in turn result in an overall reduced series resistance of the transistor element, thereby also contributing to enhanced transistor performance.

One illustrative method disclosed herein comprises forming a spacer structure on sidewalls of gate electrode structures of a plurality of transistors that are formed above a substrate, wherein the gate electrode structures comprise a gate electrode material and a cap layer formed on the gate electrode material. The method further comprises forming drain and source regions using the gate electrode structures and the sidewall spacer structures as an implantation mask. Furthermore, an etch process is performed to remove the cap layers and reduce the size of the sidewall spacer structures. Finally, the method comprises forming one or more strain-inducing layers above the plurality of transistors.

A further illustrative method disclosed herein comprises forming a gate electrode structure of a transistor above a semiconductor region, wherein the gate electrode structure comprises a gate electrode material and a cap layer. Furthermore, a sidewall spacer structure is formed on sidewalls of the gate electrode structure. Moreover, the method comprises forming drain and source regions by using the gate electrode structure including the cap layer and the sidewall spacer structure as an implantation mask. Additionally, the cap layer and a portion of the sidewall spacer structure are removed in a single step chemical etch process and a strain-inducing dielectric material is formed above the transistor.

One illustrative semiconductor device disclosed herein comprises a gate electrode structure of a transistor that is formed above a semiconductor region, wherein the gate electrode structure comprises a sidewall spacer structure having a specified width. The semiconductor device further comprises drain and source regions formed in the semiconductor region and comprising shallow extension regions and deeper drain and source areas, wherein the extension regions define a channel region of the transistor and wherein the deeper drain and source areas have a first lateral offset to the channel region. The semiconductor device further comprises a strain-inducing semiconductor alloy formed at least in a portion of the drain and source regions, wherein the strain-inducing semiconductor alloy induces a strain in the channel region. Additionally, the semiconductor device comprises metal silicide regions formed in the drain and source regions, wherein the metal silicide regions have a second lateral offset to the channel region that is less than the first lateral offset.

### BRIEF DESCRIPTION OF THE DRAWINGS

The disclosure may be understood by reference to the following description taken in conjunction with the accompanying drawings, in which like reference numerals identify like elements, and in which:

FIGS. 1a-1d schematically illustrate cross-sectional views of a semiconductor device comprising a plurality of transistors at various manufacturing stages in forming strain-inducing semiconductor alloys in at least some of the transistors, while maintaining a cap layer on corresponding gate electrode structures, according to illustrative embodiments;

FIGS. 1e-1g schematically illustrate cross-sectional views of the semiconductor device in further advanced manufacturing stages for forming drain and source regions on the basis of appropriately designed sidewall spacer structures, wherein the cap layer is still positioned on the gate electrode structures, according to further illustrative embodiments;

FIG. 1h schematically illustrates the semiconductor device during a common etch process for removing the cap layer and reducing the size of the sidewall spacer structure, according to illustrative embodiments; and

FIG. 1i schematically illustrates a cross-sectional view of the semiconductor device in a further advanced manufacturing stage, in which a strain-inducing dielectric material may be formed above the plurality of transistors, according to still further illustrative embodiments.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

Generally, the present disclosure provides semiconductor devices and process techniques for “relaxing” surface topography prior to the deposition of strain-inducing dielectric materials above the basic transistor structures, while at the same time maintaining an efficient cap layer on the gate electrodes which may be used as an efficient additional implantation blocking material and which may also provide enhanced integrity of the gate electrode structure during the reduction of the sidewall spacer structure. In some illustrative embodiments, the cap layer may be removed in a reliable manner while at the same time reducing the size of the spacer structures in a controllable manner, since the finally obtained size and thus width of the sidewall spacer structure may be adjusted on the basis of the initial thickness of the cap layer and the removal rate of the corresponding etch chemistry. For example, in one illustrative embodiment, the etch process may be performed as a single step wet chemical etch process, which is to be understood as an etch process without an intermediate process step so that the device may continuously be exposed to the wet chemical etch chemistry. For this purpose, in some embodiments, hydrofluorine ethylene glycol (HFEG) may be used. In further illustrative aspects disclosed herein, additionally to enhancing the efficiency of the strain-inducing mechanism by reducing the size of the final spacer structure prior to depositing the highly stressed dielectric material, a strain-inducing semiconductor alloy, such as silicon/germanium, silicon/carbon, silicon/germanium/tin and the like, may be formed on the basis of a “disposable” spacer approach in which the cap layer may be maintained even after removal of the disposable spacers used as an etch mask and/or growth mask during deposition of the strain-inducing semiconductor alloy by forming an appropriate etch stop material on the cap layer. Consequently, even in sophisticated applications, an efficient reduction in size of the final spacer structure may be accomplished while the cap layer may still provide gate electrode integrity, for instance with respect to aggressive cleaning processes and etch processes, while nevertheless well-established disposable spacer approaches may be used during the formation of the strain-inducing semiconductor alloy. In this manner, transistor elements may be provided, such as N-channel transistors, in which a reduced drain/source contact resistance may be obtained due to metal silicide that may be positioned closer to the channel region. Furthermore, electron mobility and thus drive current may be enhanced more effectively since a corresponding tensile stressed dielectric material may be positioned with reduced offset to the channel region, while also the metal silicide may provide additional tensile strain. Furthermore, due to the reduced width of the final sidewall spacer structure, relaxed deposition conditions may be provided for the deposition of the highly stressed dielectric material, thereby also enabling the deposition of an increased amount of the stressed dielectric material. Similar advantages may also be obtained for P-channel transistors, wherein, in one or both types of transistors, a strain-inducing semiconductor alloy may also be provided, substantially without contributing increased process complexity compared to conventional CMOS strategies.

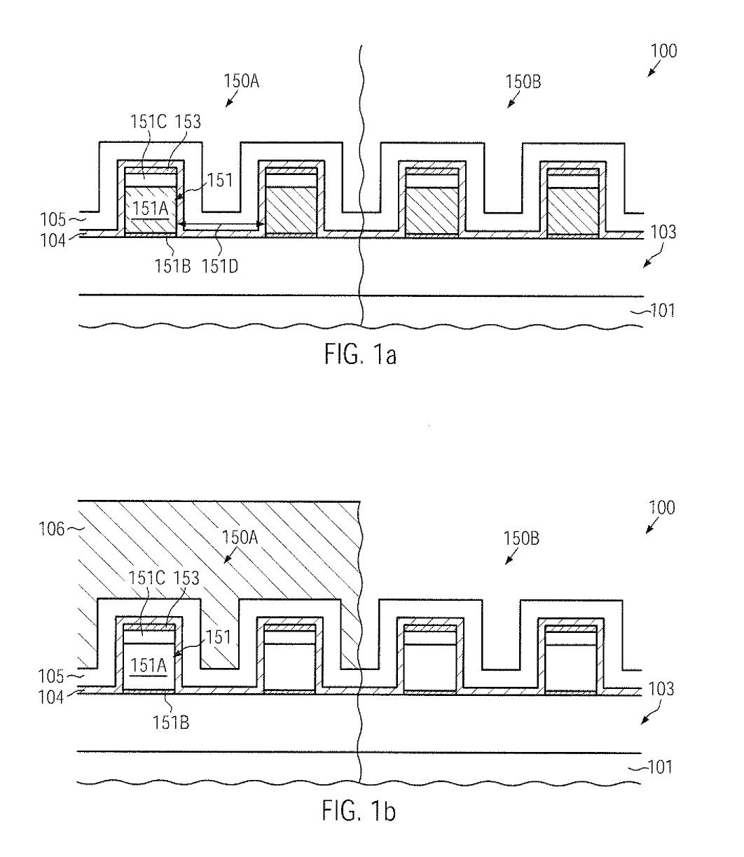

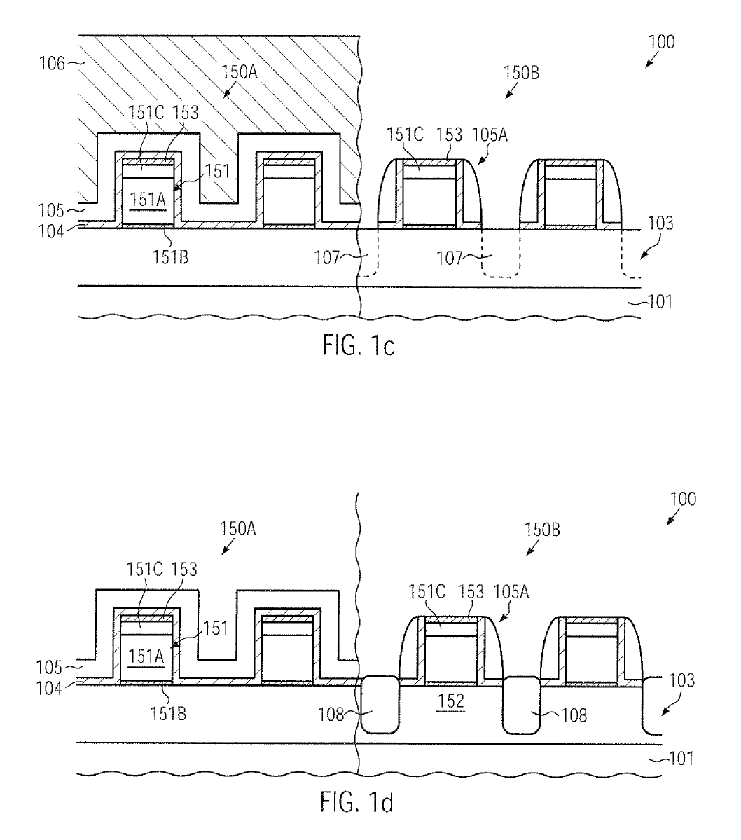

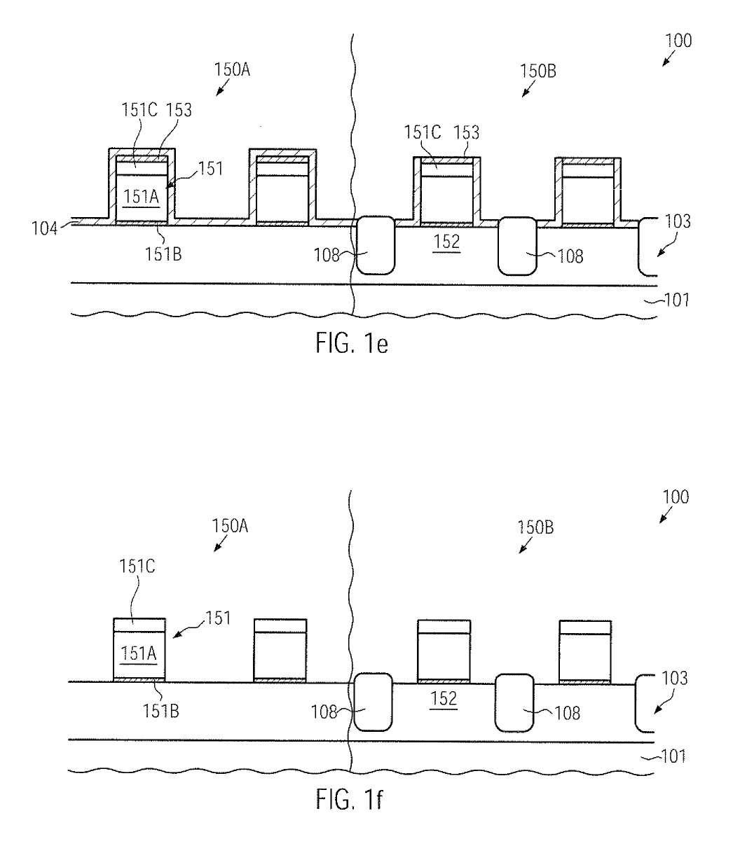

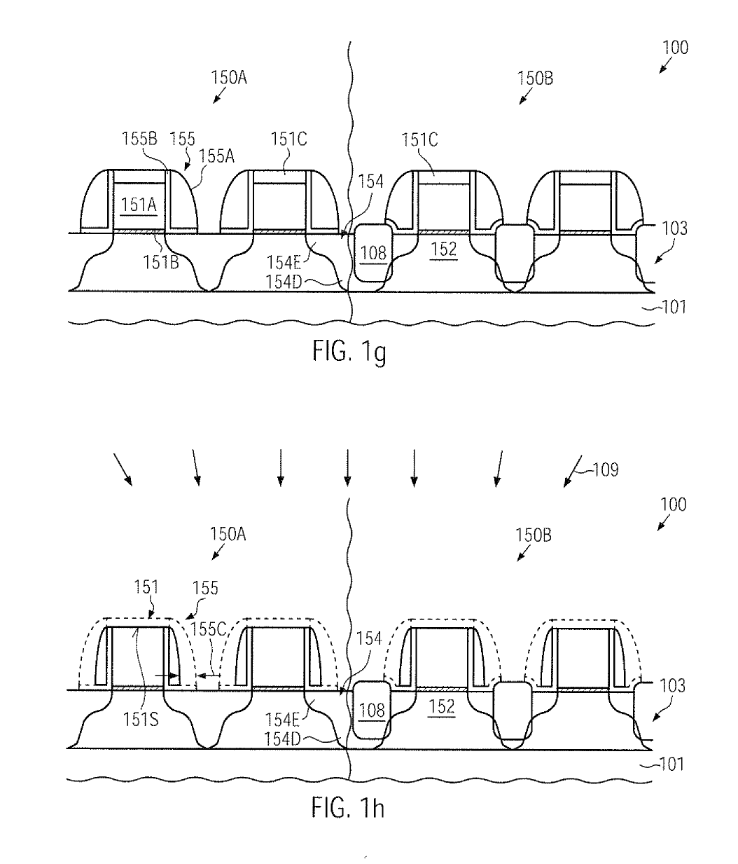

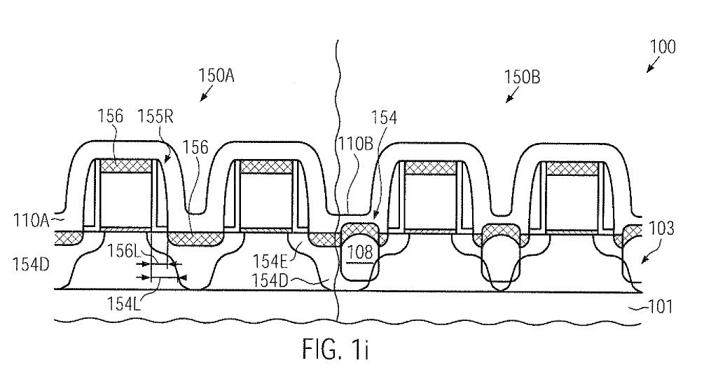

FIG. 1a schematically illustrates a cross-sectional view of a semiconductor device 100 comprising a substrate 101 above which is formed a silicon-containing semiconductor layer 103. The substrate 101 may represent any appropriate carrier material for forming thereabove the semiconductor layer 103. In one illustrative embodiment (not shown), the semiconductor device 100 may comprise a buried insulating layer, for instance in the form of silicon dioxide, silicon oxynitride, silicon nitride and the like, that may be provided between the substrate 101 and the semiconductor layer 103, thereby defining a silicon-on-insulator (SOI) configuration. In other cases, the semiconductor layer 103 may represent an upper portion of a substantially crystalline material of the substrate 101, which may also be referred to herein as a bulk configuration. It should be appreciated that the semiconductor layer 103 may have any appropriate composition and thickness as may be required for forming advanced transistor elements 150A, 150B in and above the semiconductor layer 103. In the manufacturing stage shown, the plurality of transistors 150A, 150B may comprise a gate electrode structure 151, which may in turn comprise a gate electrode material 151A, such as polysilicon, a gate insulation layer 151B that separates the gate electrode material 151A from a channel region, and a cap layer 151C, which may be provided in the form of a dielectric material and the like to provide enhanced integrity of the gate electrode material 151A during the further processing. As previously explained, a gate length of the transistors 150A, 150B, i.e., in FIG. 1a the horizontal extension of the gate electrode material 151A, may be approximately 50 nm and less in sophisticated applications. Furthermore, at least some of the transistors 150A, 150B may be provided in densely packed device regions, in which neighboring gate electrode structures 151 may have a lateral distance of several hundred nanometers and significantly less, wherein the lateral distance is to be understood as the distance between the gate electrode materials 151A, as indicated by 151D. It should be appreciated that, in the embodiment shown, the transistors 150A may represent N-channel transistors and the transistors 150B may represent P-channel transistors, while it should be appreciated, however, that any other configuration may be used. For instance, N-channel transistors and a P-channel transistor may be positioned in close proximity, wherein an intermediate isolation structure may be provided or not, depending on the overall device requirements.

Moreover, in the manufacturing stage shown, the semiconductor device may further comprise an etch stop layer 153, which may be comprised of any appropriate material, such as silicon dioxide, silicon oxynitride and the like, to provide a desired etch stop capability during the further processing, as will be described later on. Moreover, a first mask layer 104, for instance in the form of a silicon dioxide layer, and a second mask layer 105, for instance comprised of silicon nitride, may be formed above the transistors 150A, 150B. The mask layers 104, 105 may be provided so as to enable the formation of disposable spacer elements on at least some of the transistors 150A, 150B, such as the transistors 150B.

The semiconductor device 100 as shown in FIG. 1a may be formed on the basis of the following processes. After forming appropriate isolation structures (not shown), for instance in the form of shallow trench isolations, which may be accomplished on the basis of well-established process techniques, a dielectric material for the gate insulation layer 151B and the gate electrode material 151A, possibly in combination with material of the cap layer 151C, may be formed on the basis of oxidation and/or deposition and/or surface treatment techniques according to well-established approaches. Thereafter, a sophisticated patterning process may be performed, including sophisticated lithography and etch techniques, so as to obtain the gate electrode structure 151. During the corresponding patterning processes, also the cap material may be patterned so as to obtain the cap layer 151C. In some illustrative embodiments, also material of the etch stop layer 153 may be deposited or may be formed by surface treatment, such as oxidizing a silicon nitride material in an oxygen-containing plasma ambient and the like. Thus, a moderately dense material may be formed for the etch stop layer 153, which may have a high degree of etch selectivity with respect to the cap layer 151C. Thereafter, the mask layers 104 and 105 may be deposited, for instance, by thermally activated CVD recipes, plasma enhanced CVD and the like. During the deposition of the layers 104, 105, the combined thickness thereof may be appropriately selected so as to obtain a desired lateral offset, for instance for the transistors 150B in a later manufacturing stage, when forming corresponding cavities in the semiconductor layer 103.

FIG. 1b schematically illustrates the semiconductor device 100 in an advanced manufacturing stage in which a mask 106 may be provided to cover device regions in which corresponding disposable spacer elements are not required. In the embodiment shown, the transistors 150A may be covered by the mask 106, while the transistors 150B may be exposed. The mask 106 may be formed of any appropriate material, such as resist material, resist material in combination with conventional dielectric materials used as hard mask materials and the like. For this purpose, the mask material may be deposited, for instance, by spin coating, deposition and the like, and may be patterned on the basis of well-established photolithography techniques. For instance, when provided in the form of a resist material, the exposed portion or non-exposed portion, depending on the type of resist material used, may be removed to expose the transistors 150B. In other cases, a corresponding resist mask may be used for patterning a hard mask material if required.

FIG. 1c schematically illustrates the semiconductor device 100 in a further advanced manufacturing stage in which “disposable” spacer structures 105A are formed on sidewalls of the transistors 150B, while the transistors 150A are still covered by the mask 106. The spacer structure 105A may be formed on the basis of well-established anisotropic etch techniques, in which the mask layer 105 may be etched selectively with respect to the mask layer 104, which may then be etched selectively with respect to the semiconductor layer 103. For this purpose, well-established process recipes are available and may be employed in this manufacturing stage. In other illustrative embodiments, a pronounced etch selectivity with respect to the layers 104 and 105 may not be required as long as the corresponding etch process may be reliably stopped on the semiconductor layer 103. Furthermore, during the corresponding etch process, the additional etch stop layer 153 may maintain integrity of the cap layer 151C since the etch stop layer 153 may provide an additional thickness during the etch process so that exposed portions of the mask layer 104 may be reliably removed while nevertheless maintaining at least a portion of the etch stop layer 153 on the cap layer 151C. Moreover, as previously explained, in some illustrative embodiments, the etch stop layer 153 may be formed by appropriate deposition and/or surface treatment procedures so as to obtain a moderately high material density and thus a reduced etch rate compared to the mask layer 104, even if comprised of a similar material, such as a silicon dioxide-based material. There-after, a further etch process may be performed to form respective cavities 107, as indicated by the dashed lines, wherein the spacer structure 105A may act as an etch mask, while the mask 106 may still cover the transistors 150A or may be removed prior to the corresponding cavity etch process, depending on the overall process strategy. Appropriate etch recipes for forming the cavities 107 in the semiconductor layer 103 are well established, for instance, for silicon-based semiconductor material in the presence of silicon dioxide, silicon nitride and the like. Thus, respective etch recipes may also be used in this case, thereby providing a high degree of compatibility with conventional process strategies.

FIG. 1d schematically illustrates the semiconductor device 100 with a semiconductor alloy 108 formed at least in the cavities 107. To this end, well-established selective epitaxial growth techniques may be applied in which process parameters are typically selected such that a significant material deposition is restricted to crystalline silicon areas, while a material deposition on dielectric surface areas, such as the spacer structure 105A and the mask layer 105, or the mask 106 (FIG. 1c) if still present in the form of a hard mask material, may be negligible. For instance, in some illustrative embodiments, the semiconductor alloy 108 may be provided in the form of a silicon/germanium alloy, which may therefore grow on the remaining silicon-based material of the layer 103 in a compressively stressed state, thereby also exerting a corresponding compressive stress on the adjacent channel regions 152 of the transistors 150B. In other illustrative embodiments, the strain-inducing semiconductor alloy 108 may be provided in the form of a silicon/carbon material, thereby inducing a tensile strain in the adjacent channel regions 152, which may be advantageous when the transistors 150B represent N-channel transistors. Also, other material compositions, such as silicon/tin, silicon/germanium/tin and the like, may be formed during the selective epitaxial growth process by using appropriate precursor materials.

FIG. 1e schematically illustrates the semiconductor device 100 in a further advanced manufacturing stage. As illustrated, the mask layer 105 and a portion of the spacer structure 105A comprised of material of the mask layer 105, may be removed. For this purpose, any appropriate etch recipe may be used, such as a wet chemical etch process based on phosphoric acid, when the mask layer 105 may be provided in the form of a silicon nitride material. In some illustrative embodiments, during the corresponding etch process, the mask 106 may also be removed, if comprised of a corresponding material such as silicon nitride, when the mask 106 may have been maintained during the selective epitaxial growth process for forming the strain-inducing semiconductor alloy 108. Hence, well-established etch techniques may be used for removing at least a portion of the mask materials, such as the layer 105 and possibly the mask 106, while the mask layer 104 in combination with the etch stop layer 153 may maintain integrity of the cap layer 151C in the transistors 150B, even if the cap layers 151C are comprised of the same or a similar material as the mask layer 105. For instance, frequently, silicon nitride may be used as material of the cap layer 151C, thereby providing a high degree of compatibility with conventional process sequences in forming appropriate cap materials on polysilicon-based gate electrodes. Thereafter, a further etch process may be performed, for instance on the basis of hydrofluoric acid (HF), in order to remove the mask layer 104 selectively with respect to the gate electrode material 151A and the semiconductor materials 108 and 103. Moreover, the corresponding etch process is also highly selective with respect to the cap layers 151C.

FIG. 1f schematically illustrates the semiconductor device 100 after the above-described process sequence. Hence, the transistors 150A, 150B comprise the gate electrode structures 151 in an “exposed” state, while nevertheless the cap layers 151C may still be positioned on the gate electrode materials 151A. Consequently, during the further processing of the semiconductor device 100, i.e., the incorporation of appropriate dopant species to establish the desired dopant profile in the semiconductor material 103 and the semiconductor alloy 108 by ion implantation, the cap layer 151C may provide additional diffusion blocking capabilities, in particular in view of P-channel transistors, in which typically boron may be used as an implant species that may readily penetrate into the gate insulation layer 151B and finally into the channel region 152. Consequently, by maintaining the cap layer 151C, an increased process margin may be obtained with respect to the subsequent implantation cycles, which may thus result in enhanced transistor performance, since an increased implantation energy and/or dose may be used during the subsequent implantation cycles or for given implantation parameters for a well-established process recipe, the degree of boron penetration into the gate insulation layer 151B and the channel region 152 may be reduced.

FIG. 1g schematically illustrates the semiconductor device 100 in a further advanced manufacturing stage. As shown, sidewall spacer structures 155 are formed on the gate electrode structures 151 as is required for defining an appropriate dopant profile for drain and source regions 154. For example, in the embodiment shown, the sidewall spacer structures 155 may comprise a single spacer element 155A in combination with an etch stop liner 155B, while in other cases (not shown) two or more individual spacer elements, such as the spacers 155A in combination with appropriate liner materials, may be provided, depending on the complexity of the dopant profile of the drain and source regions 154. Thus, for the embodiment shown, the drain and source regions 154 may have shallow extension regions 154E, which may be formed on the basis of an implantation process using the gate electrode structure 151 including the cap layer 151C (FIG. 1f) as an implantation mask, possibly in combination with an offset spacer element. Thereafter, the spacer structures 155 may be formed, for instance, by depositing the liner material 155B and a spacer material, which may subsequently be patterned by well-established anisotropic etch techniques to obtain the spacer elements 155A. Using the sidewall spacer structure 155 and the cap layer 151C as an implantation mask, deeper drain and source areas 154D may be obtained, wherein the cap layer 151C may reduce or substantially avoid penetration of the gate insulation layer 151B and/or the channel region 152, in particular for P-channel transistors, such as the transistors 150B. It should be appreciated that appropriate masking regimes may be used to selectively implant the dopant species as required for the transistors 150A, 150B. Furthermore, the corresponding implantation cycles may also include respective pre-amorphization implantations, processes for incorporating implantation regions of increased counter doping with respect to the drain and source regions 154, which may also be referred to as halo implantation, and the like. Thereafter, appropriate anneal processes may be performed to activate the dopant species and also to re-crystallize implantation-induced damage.

FIG. 1h schematically illustrates the semiconductor device 100 during a material removal process 109 that is designed to remove the cap layer 151C and also reduce the width of the sidewall spacer structure 155. As previously explained, for a given lateral distance 151D (FIG. 1a) for the gate electrode structures 151, the sidewall spacer structure 155 may additionally result in a more complex surface topography, thereby increasing the constraints for a corresponding deposition process for forming a highly stressed dielectric material in a later manufacturing stage. Furthermore, the initial width of the sidewall spacer structure 155 may, in some illustrative embodiments, also be considered as inappropriate for defining a lateral offset of metal silicide regions to be formed in the drain and source regions 154. Thus, also in this case, a reduction of the width of the spacer structure 155 may result in overall enhanced performance of the transistors 150A, 150B. Furthermore, the cap layer 151C may also be removed from the gate electrode material 151A, which in one illustrative embodiment may be accomplished by performing a single step wet chemical etch process, which is to be understood as an etch process performed on the basis of a wet chemical etch chemistry without any interruption exposing the device 100 to the reactive etch ambient of the process 109. In this case, the degree of material removal of the spacer structure 155, as is indicated by 155C, may be controlled on the basis of the effective removal rate provided by the wet chemical etch chemistry of the process 109. Furthermore, since the cap layer 151C may be completely removed during the process 109, a thickness of the cap layer 151C may be selected such that a desired degree of material removal 155C may be obtained for the spacer structure 155 without unduly exposing a surface 151S of the gate electrode material 151A to the ambient of the process 109. Hence, an initial thickness of the cap layer 151C may be selected less than an initial width of the sidewall spacer structure 155 and thus an initial thickness of a corresponding spacer layer used for forming the sidewall spacer element 155A (FIG. 1g). Consequently, in this case, highly aggressive yet very efficient cleaning agents may be used during the process 109, thereby providing a high degree of integrity of the surface 151S during most of the corresponding removal process, while nevertheless also removing material of the spacer structure 155 in a highly controllable and efficient manner. Upon exposing the surface 151S, the process 109 may be discontinued, thereby restricting exposure of the surface 151S to the aggressive ambient 109 to only a very short time period, consequently the polycrystalline surface 151S may be maintained with a moderately high degree of crystalline quality, thereby also providing enhanced conditions during the subsequent metal silicide process. In one illustrative embodiment, the wet chemical etch ambient may be established on the basis of hydrofluorine ethylene glycol (HFEG), which may have an etch rate for silicon nitride and silicon dioxide of approximately 1:1.3 so that the cap layer 151C may be reliably removed while at the same time reducing the width of the spacer structure 155 including the etch stop liner 155B (FIG. 1g).

Thereafter, the further processing may be continued by forming metal silicide regions in the exposed gate electrode material 151A and exposed portions of the drain and source regions 154. Due to the reduced width of the sidewall spacer structure 155, as indicated by 155C, the corresponding metal silicide may be positioned closer to the channel regions 152, thereby reducing the overall series resistance of the conductive path in the transistors 150A, 150B. Consequently, performance of the transistors 150A, 150B may be increased, irrespective of the conductivity type thereof.

FIG. 1i schematically illustrates the semiconductor device 100 in a further advanced manufacturing stage. As illustrated, metal silicide regions 156 are formed in the drain and source regions 154 and in the gate electrode structure 151, which have formed thereon a reduced sidewall spacer structure 155R obtained by the previously performed material removal process 109 (FIG. 1h). It should be appreciated that, due to the fact that metal silicide regions 156 are formed on the basis of the spacer structure 155R, while deep drain and source areas 154D have been formed on the basis of sidewall spacer structures 155 (FIG. 1g), a lateral offset 156L of the metal silicide regions 156 with respect to the gate electrode 151 is less than a lateral offset 154L of the deeper drain and source areas 154D. Due to the reduced lateral offset 156L, the contact resistance of the transistors 150A, 150B may be reduced compared to a transistor configuration in which the metal silicide regions may be formed on the basis of the initial width of the sidewall spacer structure 155 (FIG. 1g). Furthermore, in the manufacturing stage shown, one or more strain-inducing dielectric materials may be formed above at least some of the transistors 150A, 150B. In the embodiment shown, a strain-inducing layer 110A may be formed above the transistors 150A, wherein an internal stress level of the material 110A may induce a corresponding type of strain in the channel regions 152 thereof so as to increase charge carrier mobility therein. For example, the layer 110A may be provided as a tensile stressed dielectric material which may be appropriate for enhancing performance of N-channel transistors. Additionally, the transistors 150B may have formed thereabove a dielectric material 110B having a high internal stress level so as to provide the same type of strain as the strain-inducing semiconductor alloy 108. For instance, the material 110B may be provided with high compressive stress when the semiconductor alloy 108 also provides compressive strain in the adjacent channel region. As previously explained, due to the reduced width of the spacer structure 155R, any constraints with respect to the gap fill capabilities of deposition processes used for forming the materials 110A, 110B may be less pronounced and thus an increased amount of material, i.e., an increased layer thickness, may be used and/or, for a given layer thickness, increased flexibility in providing the one or more stressed dielectric materials 110A, 110B may be achieved.

The one or more stressed dielectric materials 110A, 110B may be formed in accordance with well-established process techniques yet, however, using adapted process parameters, for instance with respect to providing an increased layer thickness and/or higher internal stress levels, since less restrictive constraints are to be respected during the corresponding deposition process, which may allow the selection of process parameters that may provide increased internal stress levels. For instance, a tensile stressed or compressive stressed dielectric material may be deposited, for instance, by plasma enhanced CVD techniques and the like, followed by a removal of an unwanted portion thereof, which may be accomplished by lithography and etch techniques. Thereafter, the dielectric material of different type of internal stress may be deposited and a respective unwanted portion thereof may be removed, thereby obtaining the configuration as illustrated in FIG. 1i. It should be appreciated that the above-described process sequence may also include the deposition or formation of appropriate etch stop or etch control materials as may be required for an efficient patterning of the corresponding dielectric layers. In other cases, only one type of stressed dielectric material may be provided, possibly in combination with a corresponding stress relaxation above specific device areas. For instance, if the strain-inducing mechanism of the semiconductor alloy 108 is considered appropriate without any additional overlying stressed dielectric material, the dielectric material may be provided with an internal stress level that provides performance enhancement of the transistors 150A, wherein an even further increased amount of tensile stressed material may be deposited as any constraints with respect to a further patterning of this material and the deposition of a subsequent material in combination with a patterning thereof may not have to be taken into consideration. If desired, a stress relaxation implantation may be performed to reduce the stress level above the transistors 150B. It should be appreciated, however, that any other process strategy may be used to form a highly stressed dielectric material above at least some of the transistors 150A, 150B, wherein the enhanced surface topography obtained by the reduced spacer structure 155R may provide a reduced lateral offset of the stressed material with respect to the channel regions 152 and for generally relaxed deposition conditions when depositing the highly stressed dielectric material.

As a result, the present disclosure provides semiconductor devices and manufacturing techniques in which metal silicide may be positioned in close proximity to the channel region, while also the stress transfer mechanism of a dielectric material may be enhanced by removing material of a sidewall spacer structure prior to forming the metal silicide regions. Additionally, a cap layer may be maintained on the gate electrode structures during corresponding implantation sequences for defining the dopant profile for the drain and source regions, thereby also contributing to increased device performance and reliability due to the increased ion blocking effect of the gate electrode structure in combination with the cap material. Furthermore, the cap material may also be maintained when an embedded semiconductor alloy is to be formed in an early manufacturing stage by providing an appropriately designed process strategy on the basis of an etch stop material while nevertheless maintaining a high degree of compatibility with conventional process strategies. In some illustrative embodiments, the removal of the cap material provided on top of the gate electrode material and a controlled material removal of the sidewall spacer structure may be accomplished by a single etch process. Hence, an efficient overall process flow may be obtained while enhancing device performance by reducing dopant penetration into the channel region, reducing a lateral distance of metal silicide regions and a highly stressed dielectric material, in particular for sophisticated device geometries.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method, comprising:
forming a spacer structure on sidewalls of gate electrode structures of a plurality of transistors formed above a substrate, said gate electrode structures comprising a gate electrode material and a cap layer formed on said gate electrode material;
forming drain and source regions using said gate electrode structures and said sidewall spacer structures as an implantation mask;
performing an etch process to remove said cap layers and reduce a size of said sidewall spacer structures; and
forming one or more strain-inducing layers above said plurality of transistors.

2. The method of claim 1, further comprising forming metal silicide regions in said drain and source regions after performing said etch process.

3. The method of claim 1, wherein said etch process is a wet chemical etch process.

4. The method of claim 3, wherein said etch process is performed on the basis of hydrofluorine ethylene glycol (HFEG).

5. The method of claim 1, wherein forming said one or more strain-inducing layers comprises forming a tensile stressed dielectric material above an N-channel transistor of said plurality of transistors and forming a compressively stressed dielectric material above a P-channel transistor of said plurality of transistors.

6. The method of claim 1, further comprising forming a strain-inducing semiconductor alloy adjacent to at least some of said plurality of transistors prior to forming said drain and source regions.

7. The method of claim 6, further comprising forming an etch stop layer on said cap layers and forming a disposable spacer structure on sidewalls of the gate electrodes of said at least some of the transistors while covering the other ones of said plurality of transistors with a mask layer.

8. The method of claim 7, further comprising removing said disposable spacer structures and said mask layer in a common removal process and using said etch stop layer as an etch stop so as to substantially maintain said cap layers.

9. The method of claim 6, wherein said strain-inducing alloy comprises at least one of germanium, tin and carbon.

10. The method of claim 1, wherein said sidewall spacer structures are formed with a width that is equal to or greater than a thickness of said cap layers.

11. The method of claim 1, further comprising forming metal silicide regions in said drain and source regions prior to performing said etch process.

12. A method, comprising:
forming a gate electrode structure of a transistor above a semiconductor region, said gate electrode structure comprising a gate electrode material and a cap layer;
forming a sidewall spacer structure on sidewalls of said gate electrode structure;
forming drain and source regions by using said gate electrode structure including said cap layer and said sidewall spacer structure as an implantation mask;
removing said cap layer and a portion of said sidewall spacer structure in a single step wet chemical etch process; and
forming a strain-inducing dielectric material above said transistor.

13. The method of claim 12, wherein an etchant used in said single step wet chemical etch process comprises hydrofluorine ethylene glycol.

14. The method of claim 13, further comprising forming an etch stop layer on said cap layer and removing said etch stop layer prior to forming said sidewall spacer structure.

15. The method of claim 12, further comprising forming a strain-inducing semiconductor alloy in said semiconductor region laterally adjacent to said gate electrode structure prior to forming said sidewall spacer structure.

16. The method of claim 15, wherein forming said strain-inducing semiconductor alloy comprises forming a disposable spacer structure on sidewalls of said gate electrode structure, forming cavities in said semiconductor region and forming said semiconductor alloy at least in said cavities.

17. The method of claim 16, further comprising removing said disposable spacer structure and using said etch stop layer as an etch stop so as to substantially maintain said cap layer.

18. The method of claim 12, further comprising forming metal silicide regions in said drain and source regions after performing said single step wet chemical etch process.

19. A semiconductor device, comprising:
a gate electrode structure of a transistor formed above a semiconductor region, said gate electrode structure comprising a sidewall spacer structure having a specified width;
drain and source regions formed in said semiconductor region, said drain and source regions comprising shallow extension regions and deeper drain and source areas, said extension regions defining a channel region of said transistor and said deeper drain and source areas having a first lateral offset to said channel region;
a strain-inducing semiconductor alloy formed at least in a portion of said drain and source regions, said strain-inducing semiconductor alloy inducing a strain in said channel region; and
metal silicide regions formed in said drain and source regions, said metal silicide regions having a second lateral offset to said channel region that is less than said first lateral offset.

20. The semiconductor device of claim 19, further comprising a strain-inducing dielectric material formed above said transistor, wherein said strain-inducing dielectric material and said strain-inducing semiconductor alloy induce the same type of strain in said channel region.

21. The semiconductor device of claim 19, wherein said channel length is less than approximately 50 nm.
